(19) United States
(12) Patent Application Publication
(10) Pub. No.: US 2008/0116318 A1
(43) Pub. Date: May 22, 2008

(54) Galley controller panel unit

(75) Inventors: Mark Edward Wesley, San Diego, CA (US); Timothy Andrew Birkmann, Corona, CA (US); Brian Douglas Stamm, Seal Beach, CA (US); Craig Cunningham, Old Northants (GB)

Correspondence Address: DRINKER BIDDLE & REATH LLP;ATTN: PATENT DOCKET DEPT., 191 N. WACKER DRIVE, SUITE 3700, CHICAGO, IL, 60606, US

(73) Assignee: B/E Aerospace, Inc., Wellington, FL (US)

(21) Appl. No.: 11/985,916

(22) Filed: Nov. 19, 2007

Related U.S. Application Data
(60) Provisional application No. 60/866,868, filed on Nov. 22, 2006.

(51) Int. Cl. B64D 11/00; H05K 7/16; G06F 1/16

(52) U.S. Cl. 244/118.5; 248/298.1; 361/681

(57) ABSTRACT

An extendable and retractable assembly comprising a mounting member attached to a support structure disposed inside an aperture in a wall. The assembly has a telescoping arm with a first and a second end. The first end of the telescoping arm is attached to the mounting member and the second end of the telescoping arm is attached to a rotation member. A control device is connected to the second end of the telescoping arm by the rotation member. When the telescoping arm is extended such that the control device is no longer stowed inside the aperture in the wall, the control device can rotate at least partially around an axis substantially perpendicular to the telescoping arm.

### CROSS-REFERENCE TO RELATED PATENT APPLICATIONS

This patent application claims the benefit of U.S. Provisional Patent Application No. 60/866,868, filed Nov. 22, 2006.

### FIELD OF THE INVENTION

The invention relates generally to extendable and retractable devices related to the management of food service.

### BACKGROUND OF THE INVENTION

Ideally, when a business needs to serve food and beverages, the customers are conveniently located at tables, a large kitchen with a staff is located nearby, and there is ample space to organize and plan the food service, and to prepare the food. However, there are many scenarios in which this is not the case and in which information regarding the food service must be readily available to staff operating in very limited space conditions. An example is a galley on an airline, bus, or ship. On an airline, for example, food and beverages are generally served to customers. There are obstacles to overcome when serving such food and beverages, including the very limited space available for the serving personnel, food, and heating and chilling equipment for the food. Maneuvering in such conditions is difficult for the staff. Moreover, galley aisles need to be kept clear for safety reasons. Food is often served on serving carts to passengers. These carts need to be properly outfitted and stocked, and, often, the cart location, cart inventory, cart food temperature, and the last sanitization of the cart needs to be tracked. Food service information needs to be available to the staff without disrupting the food service itself, creating a safety hazard by blocking an aisle, or taking up much needed space in the galley. It can thus be seen that there is a need for an extendable and retractable control device, which can provide information to staff operating in limited space, and can be stowed out of the staff's way in a wall aperture when not in use.

### BRIEF SUMMARY OF THE INVENTION

In an embodiment, an extendable and retractable assembly is provided. The assembly comprises a mounting member attached to a support structure disposed inside an aperture in a wall. The assembly has a telescoping arm with a first and a second end. The first end of the telescoping arm is attached to the mounting member and the second end of the telescoping arm is attached to a rotation member. A control device is connected to the second end of the telescoping arm by the rotation member. When the telescoping arm is extended such that the control device is no longer stowed inside the aperture in the wall, the control device can rotate at least partially around an axis substantially perpendicular to the telescoping arm. The invention does not get in the way of food service operations yet is quickly accessible when needed. These and other advantages of the invention will be apparent from the description of the invention provided herein.

### BRIEF DESCRIPTION OF THE DRAWINGS

FIG. 1 illustrates the assembly of the current invention in the retracted position.

FIG. 2 illustrates the assembly of the current invention in the extended position.

FIG. 3 illustrates the assembly of the current invention after the display device has been rotated and the arm partially retracted.

FIG. 4A illustrates a side view of the current invention in the stowed position.

FIG. 4B illustrates a perspective view of the current invention.

FIG. 4C illustrates a side view of the current invention after the control device has been partially rotated.

### DETAILED DESCRIPTION OF THE INVENTION

The invention is generally directed to a retractable and extendable control device assembly that can be stowed and retrieved from a wall aperture. The following examples depict the invention utilized in the galley of an aircraft and more particularly as part of an on-board food management system that allows a user to display data and enter data related to food service on the aircraft. The invention, however, is not limited to use in an aircraft galley or to a food management system; it is directed toward use in any environment in which users must interact with a control device in limited space. The following examples further illustrate the invention but, of course, should not be construed as in any way limiting its scope.

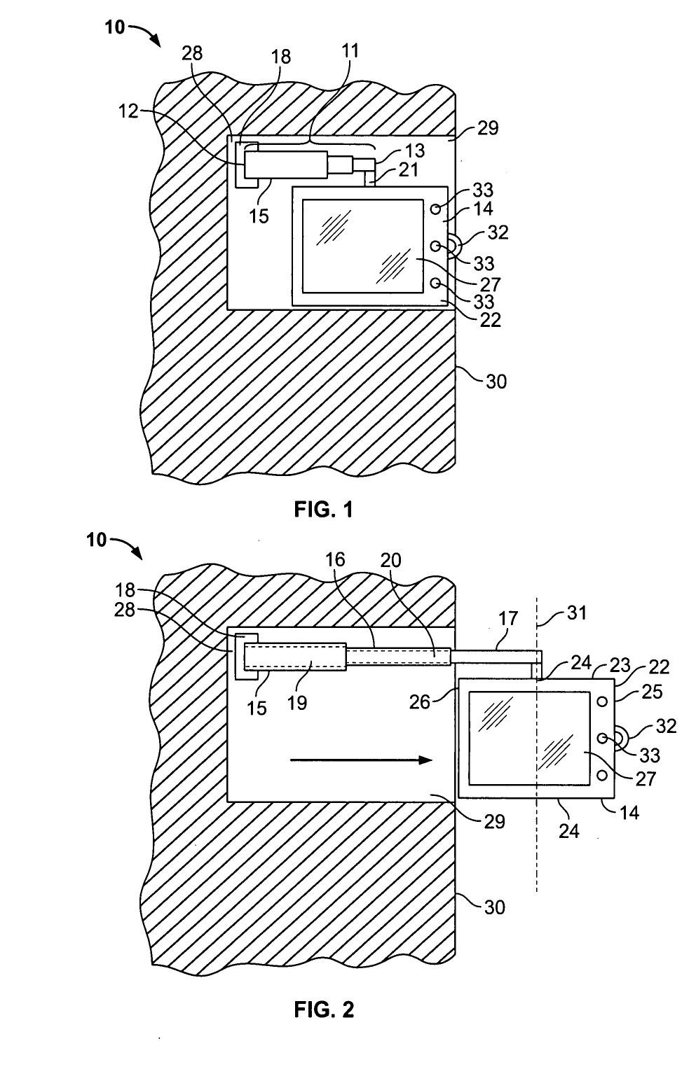

Referring to FIGS. 1-2, an embodiment of the assembly, generally labeled 10, will now be described. The assembly 10, includes a telescoping arm 11 having a first 12 and a second end 13. The first end 12 of the telescoping arm 11 is attached to a mounting member 18 and the second end 13 of the telescoping arm 11 is attached to a rotation member 21. The telescoping arm 11 provides support to the control device 14. Although other shapes are within the spirit of the invention, the telescoping arm 11 illustrated in this embodiment is substantially cylindrical in shape.

In one embodiment, the telescoping arm 11 has first 15, second 16, and third 17 sections as shown in FIGS. 1-3. The arm is not limited to three sections. The arm may have fewer or more than three sections. The first section 15 is attached to the mounting member 18. The second section 16 slides lengthwise and is telescopingly received into a first interior 19 of the first section 15 for selective extension from and retraction into the first section 15 to lengthen and shorten the arm 11. The third section 17 slides lengthwise and is telescopingly received into a second interior 20 of the second section 16 for selective extension from and retraction into the second section 16 to lengthen and shorten the arm 11.

The control device 14 is connected to the second end 13 of the telescoping arm 11 by the rotation member 21. The rotation member 21 may be connected to the third section 17. In the embodiment shown in FIGS. 1-3, the rotation member is not able to be received into the second interior 20 of the second section 16 of the telescoping arm 11. In other embodiments, the rotation member 21 may be able to be received at least partially into the telescoping arm. The control device 14 is comprised of a housing 22 and a display screen 27 for displaying data. The control device 14 may further comprise at least one control mechanism 33 for manipulating use of the control device 14. The control device 14 may be used as a user input device. In one embodiment, the control device 14 may be generally planer and substantially rectangular or square shaped and, similar to a panel, the depth of the control device 14 may be substantially smaller than the width control device 14. Other shapes and relative dimensions for the control device 14 are encompassed by the invention. In one embodiment, the display screen 27 may be a touch screen display capable of receiving and sending user input for food service management.

The mounting member 18 is mountable to a support structure 28. In the particular embodiment shown in FIGS. 1-2, the mounting member 18 is a bracket. In other embodiments other suitable mounting devices may be used to secure the telescoping arm 11 to a structure capable of supporting the weight of the telescoping arm 11 and the control device 14. The support structure 28 is disposed inside an aperture 29 in a wall 30. In the particular embodiment shown in FIGS. 1-4, the support structure 28 is disposed in the galley area of an aircraft although the invention is not limited to use on an aircraft. In the embodiment in FIGS. 1-4, the shape of the aperture 29 is substantially rectangular, and the width of the aperture 29 is greater than the width of the control device 14 but less then twice the width of the control device 14. The aperture 29 may be other shapes and dimensions.

When the telescoping arm 11 is extended such that the control device 14 is no longer stowed inside the aperture 29 in the wall 30, the control device 14 can rotate at least partially around an axis 31 that is substantially perpendicular to the telescoping arm 11. In the preferred embodiment the control device 14 can rotate substantially ninety degrees around the axis 31.

In a preferred embodiment, the housing 22 of the control device 14 is connected to the third section 17 by the rotation member 21. The housing 22 can rotate at least partially around the axis 31 that is substantially perpendicular to the telescoping arm 11 when the second 16 and third 17 sections are extended such that the housing 22 is not disposed inside the aperture 29 in the wall 30 of the aircraft. The rotation member 21 may be any mechanism or assembly that is suitable for allowing rotation of the housing 22 of the control device 14 about the axis 31.

The housing 22 has a top surface 23 and a bottom surface 24. The rotation member 21 is disposed on the top surface 23. In the preferred embodiment, the rotation member is disposed on the top surface 23 substantially near a midpoint 24 of the distance between the right side 25 and left side 26 of the control device 14. This placement allows the control device 14 to rotation in place. The rotation member 21 may be disposed elsewhere on the housing 22 in other embodiments.

The telescoping arm 11 can be retracted so that the control device 14 is substantially flush to the wall 30. In the embodiment shown in FIG. 3. The housing 22 has been rotated ninety degrees around the axis 31 perpendicular to the telescoping arm 11 and the third section 17 has been retracted at least partially into the second interior 20 of the second section 16, and the housing 22 for the control device 14 is substantially flush to the wall 30.

A handle 32 is disposed on the housing 22 of the control device 14 for actuating extension of the second section 16 from and retraction into the first interior 19 of the first section 15 and for actuating extension of the third section 17 from and retraction into the second interior 20 of the second section 16. The handle 32 is this embodiment is a finger pull handle. Other types of handles could be used in other embodiments.

The assembly may be substantially stowed inside the aperture 29 when the telescoping arm 11 is in a retracted position and the control device 14 is substantially parallel with the telescoping arm 11. The plane in which the housing 22 is disposed may be substantially aligned with the plane in which the telescoping arm 11 is disposed when the housing 22 is stowed inside the aperture 29. In the embodiment shown in FIG. 1, the housing 22 is substantially disposed inside the aperture 29 when the second section 16 is retracted into the first interior 19 of the first section 15 and the third section 17 is retracted into the second interior 20 of the second section 16.

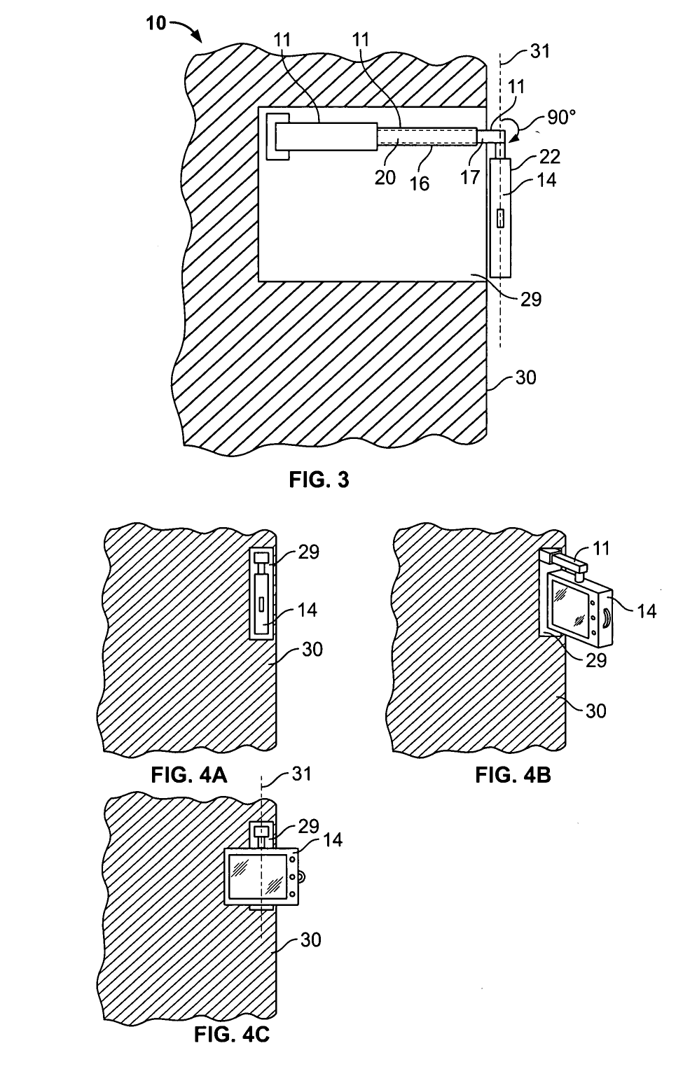

FIG. 4A illustrates a side view of the control device 14 in a stowed position inside the aperture 29 in the wall 30. FIG. 4B illustrates the telescoping arm 11 extended such that the control device 14 is no longer in the aperture 29 of the wall 30. FIG. 4C illustrates the control device 14 rotated substantially ninety degrees around the axis 31 and disposed flush against the wall 30.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. An assembly comprising:
a telescoping arm having a first and a second end;
a mounting member mountable to a support structure and attached to the first end of the telescoping arm;
a rotation member connected to the second end of the telescoping arm; and
a control device connected to the second end of the telescoping arm by the rotation member, wherein when the telescoping arm is extended the control device can rotate at least partially around an axis substantially perpendicular to the telescoping arm.

2. The assembly of claim 1, wherein the telescoping arm is substantially cylindrical in shape and supports the control device.

3. The assembly of claim 1, wherein the control device further comprises a display screen.

4. The assembly of claim 1, wherein the control device rotates substantially 90 degrees.

5. The assembly of claim 1, wherein the control device has a top surface and the rotation member is disposed on the top surface and the control device rotates substantially 90 degrees.

6. The assembly of claim 1 further comprising a handle disposed on the control device.

7. A stowable assembly comprising:
a mounting member attached to a support structure disposed inside an aperture in a wall;
a telescoping arm having a first and a second end, wherein the first end of the telescoping arm is attached to the mounting member and the second end of the telescoping arm is attached to a rotation member; and
a control panel connected to the second end of the telescoping arm by the rotation member, wherein when the telescoping arm is extended such that the control panel is no longer disposed inside the aperture in the wall, the control panel can rotate at least partially around an axis substantially perpendicular to the telescoping arm, and when the telescoping arm is retracted, the control panel is stowed inside the aperture in the wall.

8. The assembly of claim 7, wherein the telescoping arm is substantially cylindrical in shape and supports the control panel.

9. The assembly of claim 7, wherein the control panel further comprises a display screen and a control mechanism.

10. The assembly of claim 7, wherein the control panel rotates substantially 90 degrees.

11. The assembly of claim 10, wherein the control panel further comprises a touch screen display and the telescoping arm can be retracted so that the control panel is substantially flush to the wall.

12. The assembly of claim 7, further comprising a handle disposed on the control panel.

13. The assembly of claim 7, wherein the assembly is substantially disposed inside the aperture when the telescoping arm is retracted.

14. The assembly of claim 7, wherein the control panel is a user input device.

15. A stowable galley control panel system comprising:
a mounting member attached to a support structure disposed inside an aperture in a galley wall;
a support arm having first, second and third sections, the first section attached to the mounting member, the second section telescopingly received into a first interior of the first section for selective extension from and retraction into the first section to lengthen and shorten the arm, and the third section telescopingly received into a second interior of the second section for selective extension from and retraction into the second section to lengthen and shorten the arm;
a rotation member connected to the third section, the rotation member not able to be received into the second interior of the second section;
a galley control display panel having a generally planer shaped housing, the housing connected to the third section by the rotation member, wherein the plane in which the housing is disposed is substantially aligned with the plane in which the arm is disposed when the housing is stowed inside the aperture, wherein further the housing can rotate at least partially around an axis substantially perpendicular to the arm when the second and third sections are extended such that the housing is not disposed inside the aperture in the wall; and
a handle attached to the housing for actuating extension of the second section from and retraction into the first interior of the first section and for actuating extension of the third section from and retraction into the second interior of the second section.

16. The assembly of claim 15, wherein the housing rotates substantially 90 degrees.

17. The assembly of claim 15, wherein after the third section is retracted at least partially into the second interior of the second section, the housing for the galley control display panel is substantially flush to the wall.

18. The assembly of claim 15, wherein the housing is substantially disposed inside the aperture when the second section is retracted into the first interior of the first section and the third section is retracted into the second interior of the second section.

19. The assembly of claim 15, wherein the galley control display panel is a user input device having a control mechanism and the wall is disposed in an aircraft.

20. The assembly of claim 15, wherein the galley control display panel is a touch screen display panel that can receive user input and the handle is a finger pull handle.
